(19) United States
(12) Patent Application Publication
(10) Pub. No.: US 2023/0221766 A1
(43) Pub. Date: Jul. 13, 2023

(54) Electronic Devices With Rollable Displays

(71) Applicant: Apple Inc., Cupertino, CA (US)

(72) Inventors: Que Anh S Nguyen, San Jose, CA (US); Christopher D Jones, Los Gatos, CA (US)

(21) Appl. No.: 17/963,417

(22) Filed: Oct. 11, 2022

Related U.S. Application Data
(60) Provisional application No. 63/299,293, filed on Jan. 13, 2022.

(51) Int. Cl. G06F 1/16; H01L 51/00; H01L 51/52

(52) U.S. Cl. CPC G06F 1/1652; G06F 1/1616; H01L 51/0097; H01L 51/5256; H01L 2251/5338

(57) ABSTRACT

An electronic device may have a rollable display. The display may be moved between an unrolled state in which the display is planar and a rolled state in which a rollable portion of the display is rolled up for storage. The display may have a display panel with a pixel array that produces images and a transparent protective layer that overlaps the pixel array. The transparent protective layer may contain a layer of glass. The glass layer may be locally thinned in the rollable portion to facilitate rolling of the display. The display may be configured to apply compressive stress to the outwardly facing surface of the glass layer when the display is rolled up. Compressive stress in the outwardly facing glass surface may help prevent damage to the display when the display is bent during rolling operations.

This application claims the benefit of provisional patent application No. 63/299,293, filed Jan. 13, 2022, which is hereby incorporated by reference herein in its entirety.

### FIELD

This relates generally to electronic devices, and, more particularly, to electronic devices with displays.

### BACKGROUND

Electronic devices often have displays. Portability may be a concern for some devices, which tends to limit available real estate for displays.

### SUMMARY

An electronic device may have a rollable display. The display may be moved between an unrolled state in which the display is unrolled for viewing and a rolled state in which a rollable portion of the display is rolled up for storage. In the unrolled state, the display may be planar. In the rolled state, the rollable portion bends about an axis as it is rolled onto a roller for storage.

The display may have a display panel with a pixel array that produces images and a transparent protective layer that overlaps the pixel array. The transparent protective layer may contain a layer of glass. The glass layer may be locally thinned in the rollable portion to facilitate bending.

During use of the device, the outwardly facing surface of the transparent protective layer may be exposed to objects that can create scratches, whereas the inwardly facing surface of the transparent protective layer may be protected and thereby have fewer surface irregularities. To help prevent cracking in the glass layer, The display may be configured roll so that its outwardly facing surface receives compressive stress. Compressive stress in the outwardly facing glass surface may help prevent any scratches in the outwardly facing display from causing cracking or other damage to the display when the display is bent during rolling operations.

### BRIEF DESCRIPTION OF THE DRAWINGS

FIG. 1 is a schematic diagram of an illustrative electronic device in accordance with an embodiment.

FIG. 2 is a side view of an illustrative flexible display in accordance with an embodiment.

FIGS. 3, 4, and 5 are cross-sectional side views of illustrative displays with rolled portions in accordance with embodiments.

FIG. 6 is a cross-sectional side view of a portion of an illustrative electronic device in accordance with an embodiment.

FIG. 7 is a cross-sectional side view of an illustrative electronic device in which an outwardly facing surface of a display has a first area that receives compressive stress when rolled while a second area receives tensile stress in accordance with an embodiment.

FIG. 8 is a cross-sectional side view of an illustrative display with a rollable portion in accordance with an embodiment.

### DETAILED DESCRIPTION

Electronic devices may be provided with displays. Displays may be used for displaying images for users. Displays may be formed from arrays of light-emitting diode pixels or other pixels. For example, a device may have an organic light-emitting diode display or a display formed from an array of micro-light-emitting diodes (e.g., light-emitting diodes formed from crystalline semiconductor dies).

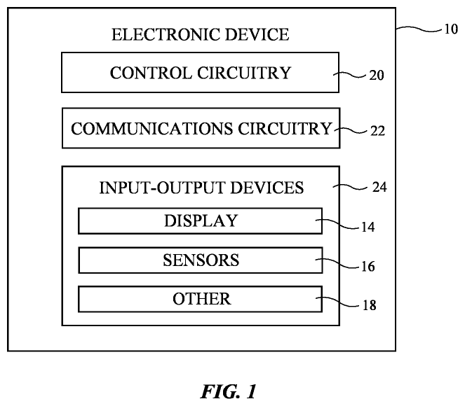

A schematic diagram of an illustrative electronic device having a display is shown in FIG. 1. Device 10 may be a cellular telephone, tablet computer, laptop computer, wristwatch device or other wearable device, a television, a stand-alone computer display or other monitor, a computer display with an embedded computer (e.g., a desktop computer), a system embedded in a vehicle, kiosk, or other embedded electronic device, a media player, or other electronic equipment. Configurations in which device 10 is a cellular telephone, tablet computer, or other portable electronic device may sometimes be described herein as an example. This is illustrative. Device 10 may, in general, be any suitable electronic device with a display.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc. During operation, control circuitry 20 may use a display and other output devices in providing a user with visual output and other output.

To support communications between device 10 and external equipment, control circuitry 20 may communicate using communications circuitry 22. Circuitry 22 may include antennas, radio-frequency transceiver circuitry (wireless transceiver circuitry), and other wireless communications circuitry and/or wired communications circuitry. Circuitry 22, which may sometimes be referred to as control circuitry and/or control and communications circuitry, may support bidirectional wireless communications between device 10 and external equipment over wired and/or wireless links (e.g., circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a wireless link operating at a frequency between 6 GHz and 300 GHz, a 60 GHz link, or other millimeter wave link, cellular telephone link, wireless local area network link, personal area network communications link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. Devices 24 may include one or more displays such as display 14. Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display or microLED display are sometimes described herein as an example.

Display 14 may have an array of pixels configured to display images for a user. The pixels may be formed as part of a display panel that is bendable. This allows device 10 to be bent about a bend axis. For example, a flexible (bendable) display in device 10 may be partly or completely rolled up so that device 10 may be placed in a compact shape for storage and may be rolled out when it is desired to view images on the display. Displays with rollable structures may sometimes be referred to herein as rollable displays, scrollable displays, flexible displays, or bendable displays. A rollable display may be completely rollable (e.g., flexible over its entire area) or may be partly rollable (e.g., one or more edge portions of a display may be provided with sufficient flexibility to be rolled whereas one or more other portions of the display may be less flexible and/or may be fixed in a planar state).

Sensors 16 in input-output devices 24 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices that capture three-dimensional images), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input. For example, buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.

If desired, electronic device 10 may include additional components (see, e.g., other devices 18 in input-output devices 24). The additional components may include haptic output devices, audio output devices such as speakers, light-emitting diodes for status indicators, light sources such as light-emitting diodes that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

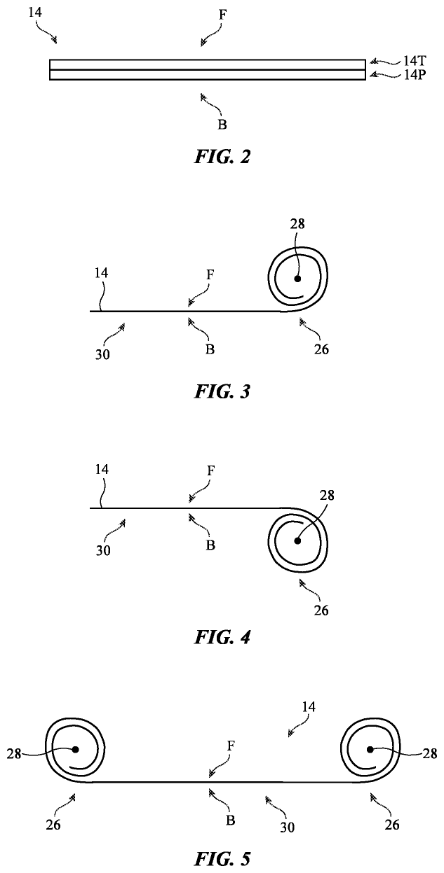

FIG. 2 is a side view of an illustrative display for electronic device 10. As shown in FIG. 2, display 14 may have a rear side B and a front side F. Front side F may face a user of the electronic device during use and may sometimes be referred to as an outwardly facing side or surface of display 14. Rear side B may face away from the user and may sometimes be referred to as an inwardly facing side or surface of display 14. The outline of display 14 when viewed by the user may be rectangular or may have other suitable shapes.

Display panel 14P of display 14 may have a pixel array such as an array of light-emitting pixels (e.g., a rectangular array of light-emitting diodes). During operation, the pixel array of panel 14P may produce images that pass through transparent protective layer 14T and that are viewable by the user on front side F. Protective layer 14T may include clear polymer, clear glass, and/or other transparent structures that allow images to be viewed while providing support (e.g., rigidity) and protection (e.g., protection from scratches and other damage) for display panel 14P. As an example, a layer of glass that is attached to the outer (front-facing) surface of panel 14P may be used to prevent display panel 14P from deforming and becoming damaged when a user's finger, computer stylus, or other external object contacts front side F of display 14. Protective polymer layers and/or other protective layers may be formed as coatings on the glass layer help prevent scratching of the glass layer. The substrate used in forming panel 14P may be flexible (e.g., display panel 14P may have a pixel array formed on a flexible polymer substrate or other flexible substrate). Protective layer 14T may also be formed from flexible structures. As a result, some or all of the area of display 14 may be flexible, which allows some or all of display 14 to be rolled up for storage.

Consider, as an example, the side view of display 14 that is shown in FIG. 3. In this example, display 14 has a planar portion such as planar portion 30 and a rolled portion 26, which has been rolled up around axis 28. When it is desired to store display 14, some or all of display 14 may be rolled up as shown by portion 26. When it is desired to increase the amount of display surface area that is viewable to the user, some or all of rolled portion 26 may be unrolled (e.g., display 14 may be unrolled so that more or all of display 14 is planar as shown by portion 30).

During rolling and/or other bending operations, the glass of layer 14T experiences compressive and tensile stress. For example, in the example of FIG. 3, the surface of the glass layer in layer 14T that faces front side F (the outwardly facing surface of the glass layer) experiences compressive stress and the surface of the glass layer in layer 14T that faces rear side R (the inwardly facing surface of the glass layer) experiences tensile stress. In general, display 14 may be rolled inwardly on its front surface (as shown in FIG. 3) or may be rolled outwardly about its rear surface (as shown in the illustrative configuration of FIG. 4).

During manufacturing, small surface irregularities (e.g., pits, grooves, or other recesses with dimensions on the orders of hundreds of nanometers) may be formed on the front and rear surfaces of the glass layer in layer 14T. During use of display 14 by a user, contact with a user's fingers, computer styluses, and/or other external objects may give rise to deeper surface irregularities (e.g., pits, grooves, and/or other recesses from scratches with dimensions on the order of one micron or more). The presence of these micron-sized surface irregularities may make the glass layer susceptible to cracking if excessive tensile stress is imposed (e.g., by rolling layer 14T so that layer 14T and the glass layer of layer 14T are characterized by an excessively small bend radius). To help ensure that the glass layer does not crack, it may be advantageous to roll display 14 inwardly towards front side F as shown in FIG. 3, rather than outwardly towards rear side B as shown in FIG. 4. In this way, the surface of the glass layer that is less susceptible to cracking (i.e., the unscratched surface of the glass layer that faces rear side B and that has smaller surface irregularities) is subjected to tensile stress during rolling about axis 28, whereas the surface of the glass layer that is more susceptible to cracking (i.e., the surface of the glass layer that faces the user and is therefore subjected to scratches from the user and has larger surface irregularities) is subjected to compressive stress during rolling about axis 28. Placing the more vulnerable surface of the glass layer in display 14T under compressive stress helps ensure that display 14 will be free from any undesired cracks or other damage.

In the examples of FIGS. 3 and 4, one edge of display 14 is being rolled. If desired, two opposing edges may be rolled for storage. This type of arrangement is shown in FIG. 5. As shown in FIG. 5, the left edge of display 14 may be sufficiently flexible to be rolled for storage and unrolled to deploy the display for use in displaying images and the right edge of the same display 14 may be sufficiently flexible to be rolled up when stored and unrolled for use.

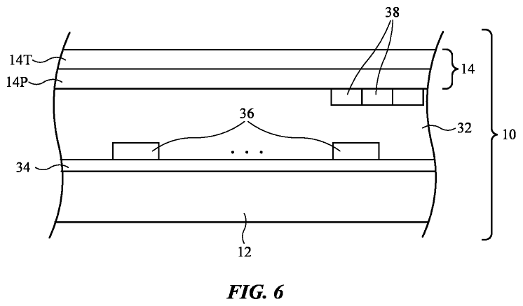

Electronic device 10 may include rigid and flexible housing structures. FIG. 6 is a cross-sectional side view of an illustrative electronic device with a housing. As shown in FIG. 6, housing 12 may have a portion forming a rear housing wall. Interior region 32 of device 10 may contain electrical components 36 mounted on substrates such a printed circuit 34. Interior region 32 may be separated from the exterior region surrounding device 10 by a rear housing wall (housing 12) and by display 14.

Display panel 14P has an array of pixels that form an image under an inwardly facing surface of protective layer 14T. Display panel 14P may be, for example, a flexible organic light-emitting diode display or a microLED display in which light-emitting pixels are formed on a flexible substrate layer (e.g., a flexible layer of polyimide or a sheet of other flexible polymer). Flexible support layer(s) for display 14 may also be formed from flexible glass, flexible metal, and/or other flexible structures. If desired, device 10 may have a support layer formed from slats such as slats 38 (e.g., slates that are each attached to left and right adjacent slats by hinge structures). Slats 38 may help maintain desired support for display 14 as display 14 is wrapped around axis 28 (of FIGS. 3, 4, and 5). Slats 38 may be formed from elongated strips of metal or other material and may extend along axes parallel to axis 28. Backside display panel support layers formed from flexible metal and/or polymer layers may also be used. In addition, layer 14T may use a flexible glass layer to help provide display panel 14P with structural support.

Layer 14T may be formed from polymer layers, one or more layers of glass, crystalline materials such as sapphire, other materials, and/or combinations of these materials. To locally increase flexibility, a portion of a glass layer in layer 14T that corresponds to the rollable portion of display 14 may be locally thinned (e.g., this portion may be thinned relative to portions of the glass layer that are not to be rolled about axis 28). The thickness of the glass layer of layer 14T (e.g., the non-thinned portions of the glass layer) may be 50-200 microns, 70-150 microns, 100-200 microns, 100-400 microns, 100-600 microns, at least 100 microns, at least 200 microns, less than 600 microns, less than 400 microns, less than 250 microns, less than 150 microns, less than 100 microns, at least 50 microns, or other suitable thickness. The thickness of the locally thinned portions of the glass layer of layer 14T may be 30-150 microns, less than 200 microns, less than 150 microns, less than 100 microns, less than 75 microns, less than 40 microns, at least 15 microns, or other suitable thickness that is thinner than the thickness of the non-thinned portions of the glass layer. Thicker glass tends to be less bendable than thinner glass, but may provide display panel 14P with more rigidity and therefore enhanced protection for panel 14P. Thinner glass allows display 14 to be rolled up tightly (with a small bend radius). The bend radius of the rolled portion of display 14 may be at least 1 mm, at least 3 mm, at least 6 mm, at least 15 mm, less than 30 mm, less than 20 mm, less than 10 mm, less than 5 mm, or other suitable value.

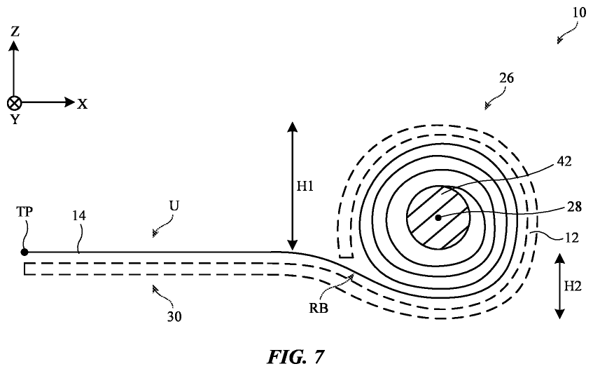

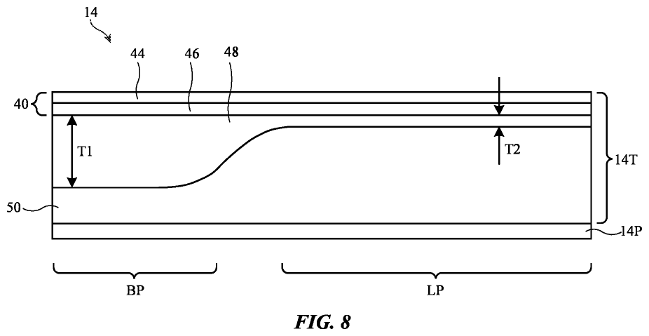

FIG. 7 is a cross-sectional side view of device 10 in an illustrative configuration in which housing 12 of device 10 has a planar portion that supports planar portion 30 of display 14 and a rolled display storage portion that supports rolled portion 26 of display 14. The outwardly facing surface of display 14 on upper side U of device 10 presents images to a user. Under planar portion 30 of display 14, housing 12 may have interdigitated fingers and/or other structures that allow the lateral size of housing 12 to be adjusted. When it is desired to extend display 14, housing 12 may be extended leftward (in the −X direction) to help support an enlarged area of portion 30 as rolled portion 26 is unrolled by being pulled out of the rolled display storage portion of housing 12. When it is desired to contract display 14, housing 12 may be contracted (left edge TP of housing 12 and display 14 may be moved to the right in the +X direction). As the planar portion of housing 12 is reduced in size in this way, spring-loaded roller 42 may rotate counterclockwise about roller axis 28 so that portion 26 of display 14 is retracted and rolled up about roller 42 for storage within the rolled display storage portion of housing 12. The diameter of the rolled display storage portion of housing 12 (H1+H2) and associated diameter of roller 42 are sufficiently large to accommodate rolled portion 26 of display 14 while maintaining a desired minimum bend radius to prevent damage to display 14.

To help minimize the distance that housing 12 protrudes above the plane of planar display portion 30, reverse bend portion RB of display 14 may be provided with a bend in the opposite direction from the bend of portion 26 and housing 12 may be shaped to conform to the bends in display 14. In the example of FIG. 7, rolled portion 26 of display 14 is wrapped upwardly around roller 42 and axis 28, whereas reverse bend portion RB is characterized by a bend in the opposite direction (e.g., display 14 is bent downwardly away from the user). As a result of the presence of reverse bend portion RB, axis 28 is moved to a lower height (lower Z position in the orientation of FIG. 7). This lowers the value of H1 (the amount of housing 12 that protrudes above the plane of planar portion 30 of display 14) and increases the value of H2 (the amount of housing 12 at the back of device 10 that extends below the plane of planar portion 30 of display 14). In reverse bend portion RB, the outer surface of the glass layer of display 14 is exposed to tension, whereas the inner surface of this glass layer is exposed to compression. The outer surface may be more sensitive to fractures due to surface damage than the inner surface, but the bend radius of display 14 in reverse bend portion RB is greater than the bend radius of display 14 in rolled portion 26, which helps reduce the tension of the outer surface to satisfactory levels. The bend radius of portion RB may be, as an example, at least two times, at least five times, or at least ten times greater than the bend radius of portion 26 (as examples). The use of a housing and display configuration for device 10 that forms a reverse bend in display 14 in this way helps reduce the visible protrusion in housing 12 that is used for rolled display storage and may thereby enhance the appearance of device 10. Configurations in which reverse bend portion RB of display 14 is omitted (e.g., configurations in which display 14 is planar except where forming rolled portion 26) may also be used.

Housing 12 may form housing walls, sidewall structures, and/or internal supporting structures (e.g., a frame, an optional midplate member, etc.) for device 10. The portions of housing 12 on the sidewalls and rear wall of device 10 may be formed from glass or other transparent structures and/or opaque structures such as metal, opaque polymer, etc.

FIG. 8 is a cross-sectional side view of display 14. In the illustrative configuration of FIG. 8, display 14 includes a flexible display panel (panel 14P) that is attached to the rear surface of transparent protective layer 14T. Layer 14T may include glass layer 48. In display portion BP, glass layer 48 may have a first thickness T1, whereas in display portion LP, glass layer 48 may be locally thinned and may be characterized by a second thickness T2 that is less than T1. The value of T1 may be 50-200 microns, 70-150 microns, 100-200 microns, 100-400 microns, 100-600 microns, at least 100 microns, at least 200 microns, less than 600 microns, less than 400 microns, less than 250 microns, less than 150 microns, less than 100 microns, at least 50 microns, or other suitable thickness that helps protect display panel 14P from damage when the surface of display 14 is contacted by an external object. The value of T2, which is sufficiently small to allow display 14 to bend, may be 30-150 microns, less than 200 microns, less than 150 microns, less than 100 microns, less than 75 microns, less than 40 microns, at least 15 microns, or other suitable thickness that allows display 14 to be rolled up while still providing rigidity that helps protect display 14. If desired, transitions between areas of different thickness in the cross-sectional profile of layer 48 may be provided with curved cross-sectional profiles or other profiles with smoothly changing thicknesses. These curved profile shapes may help avoid stress concentrations due to abrupt thickness changes and can therefore help enhance the strength of layer 48.

Protective rear coating layer 50 may be located between the rear (inwardly facing) surface of glass layer 48 and the opposing front (outwardly facing surface) of display panel 14P. Layer 50 may be formed from a flexible polymer. The presence of layer 50 may help protect the inner surface of glass layer 48 and may help planarize the inner surface of glass layer 48 to facilitate mounting of display panel 14P against this inner surface (e.g., with an additional layer of adhesive and/or using the adhesive properties of layer 50). Polymer 50 may be sufficiently flexible to bend in portion 26. The refractive index of polymer 50 may be matched to that of glass layer 48 to help minimize light reflections (e.g., by incorporating inorganic nanoparticles in the polymer material of layer 50). For example, at a wavelength of 500 nm, the refractive index of polymer 50 may differ from that of layer 48 by less than 0.15, less than 0.1, or less than 0.05 (as examples).

To help protect the front (outwardly facing) surface of display 14 from damage during use (e.g., to help prevent scratching of glass layer 48, which could weaken glass layer 48), layer 48 may be provided with a protective coating such as protective coating layer 40. Layer 40 may have one or more separate layers of material (e.g., polymer such as polyimide, etc.). As an example, layer 40 may have an inner layer (e.g., a polyimide layer or other polymer layer 46 with a thickness of 50 microns, 10-100 microns, 20-80 microns, or other suitable thickness) and an outer layer that is thinner than the inner layer (e.g., a polymer layer such as polymer layer 44 with a thickness of a few microns, at least 0.5 microns, at least 1 micron, at least 2 microns 2-10 microns, 2-8 microns, less than 15 microns, less than 7 microns, or other suitable thickness). In this type of arrangement, layer 46 may help prevent relatively deep scratches in layer 40 from penetrating to the outer surface of glass layer 48, whereas layer 44, which may be formed from a harder polymer than layer 46, may help protect the surface of layer 46 from scratching that could create haze or other visible changes to layer 40. Layer 40 faces outwardly from layer 14T and may therefore sometimes be referred to as a top coating or top coat for layer 14T, whereas layer 50 faces inwardly from layer 14T and may sometimes be referred to as a back coating, rear coating, back coating, or back coat for layer 14T.

Optional coatings may be formed on the outer surface of layer 40. These optional coatings may include, for example, anti-smudge layers, anti-fog layers, antireflection layers, anti-static layers, and/or other coatings. In some configurations, each of these functions may be implemented using a separate respective coating layer. In other configurations, a single layer may serve multiple functions.

As described above, one aspect of the present technology is the gathering and use of information such as information from input-output devices. The present disclosure contemplates that in some instances, data may be gathered that includes personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, username, password, biometric information, or any other identifying or personal information.

The present disclosure recognizes that the use of such personal information, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the United States, collection of or access to certain health data may be governed by federal and/or state laws, such as the Health Insurance Portability and Accountability Act (HIPAA), whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, the present technology can be configured to allow users to select to “opt in” or “opt out” of participation in the collection of personal information data during registration for services or anytime thereafter. In another example, users can select not to provide certain types of user data. In yet another example, users can select to limit the length of time user-specific data is maintained. In addition to providing “opt in” and “opt out” options, the present disclosure contemplates providing notifications relating to the access or use of personal information. For instance, a user may be notified upon downloading an application (“app”) that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of information that may include personal information data to implement one or more various disclosed embodiments, the present disclosure also contemplates that the various embodiments can also be implemented without the need for accessing personal information data. That is, the various embodiments of the present technology are not rendered inoperable due to the lack of all or a portion of such personal information data.

The foregoing is merely illustrative and various modifications can be made to the described embodiments. The foregoing embodiments may be implemented individually or in any combination.

What is claimed is:

1. An electronic device, comprising:
a housing;
a display coupled to the housing, wherein the display has a rollable portion configured to operate in an unrolled state and in a rolled state, wherein the display comprises:
a pixel array configured to display an image; and
a transparent protective layer that overlaps the pixel array, wherein the image is viewable through the transparent protective layer, wherein the transparent protective layer includes a glass layer having an inwardly facing surface that faces the pixel array and having an opposing outwardly facing surface, and wherein the outwardly facing surface of the glass layer in the rollable portion is compressively stressed in the rolled state.

2. The electronic device defined in claim 1 wherein, in the rolled state, the outwardly facing surface of a bent portion of the glass layer has tensile stress.

3. The electronic device defined in claim 2 wherein, in the rolled state, the rollable portion of the glass layer is characterized by a first bend radius and the bent portion is characterized by a second bend radius that is greater than the first bend radius.

4. The electronic device defined in claim 3 wherein, in the rolled state, the second bend radius is at least two times the first bend radius.

5. The electronic device defined in claim 4 wherein the glass layer is locally thinned.

6. The electronic device defined in claim 4 wherein the glass layer has a non-rollable portion that is planar in the rolled state.

7. The electronic device defined in claim 6 wherein the glass layer has a first thickness in the non-rollable portion and a second thickness that is less than the first thickness in the rollable portion.

8. The electronic device defined in claim 1 wherein the transparent protective layer includes a layer of polymer between the glass layer and the pixel array.

9. The electronic device defined in claim 8 further comprising a protective coating layer that includes a first layer of polymer on an outwardly facing surface of the glass layer and a second layer of polymer on the first layer of polymer, wherein the second layer of polymer is harder than the first layer of polymer, and wherein the second layer of polymer is thinner than the first layer of polymer.

10. The electronic device defined in claim 9 wherein the pixel array comprises a display panel with an array of light-emitting diodes.

11. The electronic device defined in claim 9 wherein the display panel comprises an organic light-emitting diode display panel.

12. An electronic device, comprising:
a housing; and
a rollable display that is coupled to the housing, wherein the rollable display is configured to operate in an unrolled state in which the rollable display is planar and displays images and a rolled state in which at least one rollable portion of the rollable display is rolled up, wherein the rollable display has a flexible display panel overlapped by a glass layer, and wherein the glass layer has a surface that faces away from the flexible display panel and that is under compressive stress in the rollable portion in the rolled state.

13. The electronic device defined in claim 12 wherein the rollable display has first and second opposing edges and first and second corresponding opposing rollable portions at the first and second edges.

14. The electronic device defined in claim 12 wherein the glass layer has a first region with a first thickness and a second region with a second thickness that is less than the first thickness.

15. The electronic device defined in claim 14 further comprising a layer of polymer between the glass layer and the flexible display panel, wherein the layer of polymer has a refractive index that differs from a refractive index of the glass layer by less than 0.1

16. The electronic device defined in claim 14 wherein, in the rollable portion of the rollable display, the glass layer has the second thickness.

17. The electronic device defined in claim 16 wherein, in the rolled state, a region of the surface of the glass layer that faces away from the flexible display panel is under tensile stress.

18. An electronic device, comprising:
a housing; and
a display coupled to the housing that is configured to transition between an unrolled configuration in which the display is planar and a rolled configuration in which a first portion of the display is planar and second portion of the display is rolled up, wherein the display has a display panel overlapped by a transparent protective layer containing a glass layer, wherein the glass layer has a first surface facing the display panel and a second surface facing away from the display panel, and wherein in the rolled configuration, the first surface of the glass layer in the second portion receives tensile stress from being rolled up and the second surface of the glass layer in the second portion receives compressive stress from being rolled up.

19. The electronic device defined in claim 18 wherein the glass layer is thinner in the second portion of the display than in the first portion of the display.

20. The electronic device defined in claim 19 wherein at least some of the second surface of the glass layer is under tensile stress in the rolled configuration.
